(19) United States
(12) Patent Application Publication
(10) Pub. No.: US 2005/0065901 A1
(43) Pub. Date: Mar. 24, 2005

(54) Methods and systems for simultaneous multiple frequency voltage generation

(75) Inventor: Bill M. Diong, El Paso, TX (US)

Correspondence Address: FULBRIGHT & JAWORSKI L.L.P., 600 CONGRESS AVE., SUITE 2400, AUSTIN, TX, 78701, US

(73) Assignee: Board of Regents, The University of Texas System

(21) Appl. No.: 10/888,553

(22) Filed: Jul. 9, 2004

Related U.S. Application Data
(60) Provisional application No. 60/485,851, filed on Jul. 9, 2003.

(51) Int. Cl. H04L 27/20; H03B 19/00; G06F 15/18; G06N 3/08

(52) U.S. Cl. 706/25; 327/113

(57) ABSTRACT

The invention includes a method of identifying at least one selected frequency, determining a number of steps and the direction of each step, calculating a plurality of stepping angles as a function of the at least one selected frequency, the number of steps, and the direction of each step, and producing. a multi-frequency voltage waveform as a function of the stepping angles, the waveform containing the at least one selected frequency. The apparatus of the invention includes a processor, a plurality of gate drivers coupled to the digital processor, a plurality of switching circuits coupled to the plurality of gate drivers, and a plurality of DC sources coupled to the plurality of switching circuits.

This patent application claims priority to, and incorporates by reference in its entirety, U.S. provisional patent application Ser. No. 60/485,851 filed on Jul. 9, 2003.

### BACKGROUND OF THE INVENTION

1. Field of the Invention

The invention relates generally to the field of power supplies. More particularly, the invention relates to a method and apparatus for simultaneous multiple frequency voltage generation.

2. Discussion of the Related Art

Present-day manufacturing facilities require the precise, deliberate application of heat to targeted workpiece sections as part of numerous processes. These processes may include, for example, hardening, brazing, annealing, tempering, bonding (curing) or removal, pre-heating, and/or melting. One important approach to workpiece heating includes electromagnetic induction, commonly referred to as induction heating. In electromagnetic induction, a workpiece and an induction coil (conductor) are placed in close proximity to each other. As an alternating current flows through the induction coil, the resulting electromagnetic field passes through and induces an electric current in the nearby workpiece, thereby heating it up due to resistance to the induced current flow.

The depth of penetration and the rate of heating of the workpiece depend on the induced current's frequency, the induced current's intensity, the specific heat of the material, the material's magnetic permeability, and the resistance of the material to the flow of current. Consequently, the frequency and power level of the current passing through the induction coil are crucial variables for obtaining the optimal result. Further, when treating workpieces with uneven geometries, such as gears, different portions of the workpiece are heated dissimilarly at a single frequency, requiring it to be processed in two steps. Hence, it would be desirable to have simultaneous multi-frequency power supplied to the coil for inductive heating in order to attain the optimal result in a single step.

Most commercially available power supplies for induction heating equipment still rely on the use of resonant circuits (also referred to as resonant power converters) to produce voltage at some single frequency and power level. In order to achieve uniform depth of treatment for workpieces with uneven geometries, heating is performed at one frequency, followed by another frequency in a sequential manner. Only recently have some induction heating power supplies that produce voltage at two selected frequencies and (corresponding) power levels simultaneously been investigated and commercially introduced.

Some existing dual-frequency power supplies are restricted to dual-frequency production of the 1^{st} and 3^{rd} harmonics, and are unable to independently adjust their levels and those of the adjacent (5^{th}, 7^{th}, etc.) harmonics. Other existing dual-frequency power supplies experience significant power losses in their high frequency sections because the devices must switch at high frequencies. Furthermore, two disparate control methods are required for the high-frequency section and the low-frequency section.

Until now, the requirements of providing a method and/or apparatus for simultaneous multiple frequency voltage generation, having (a) high efficiency and reliability, (b) sufficient frequency and power level control, (c) reduced electromagnetic interference, (d) and that facilitates higher manufacturing productivity, have not been met.

### SUMMARY OF THE INVENTION

According to an aspect of the invention, a method for producing a multi-frequency voltage waveform includes identifying at least one selected frequency, determining a number of steps and the direction of each step, calculating a plurality of stepping angles as a function of the at least one selected frequency, the number of steps, and the direction of each step, and producing a multi-frequency voltage waveform as a function of the stepping angles, the waveform containing the at least one selected frequency.

According to another aspect of the invention, an apparatus for producing a multifrequency voltage waveform includes a digital processor, the digital processor calculating a plurality of stepping angles as a function of at least one selected frequency, a number of steps, and the direction of each step, a plurality of gate drivers coupled to the digital processor, a plurality of switching circuits coupled to the plurality of gate drivers, each of the plurality of switching circuits coupled to the next in a cascade configuration for producing a multi-frequency voltage waveform as a function of the plurality of stepping angles, the waveform containing the at least one selected frequency, and a plurality of DC sources coupled to the plurality of switching circuits.

According to yet another aspect of the invention, a system is provided. The system includes a neural network, a processor for training the neural network for determining a number of steps and the direction of each step, calculating a plurality of stepping angles as a function of the at least one selected frequency, the number of steps, and the direction of each step, and producing a multi-frequency voltage waveform as a function of the stepping angles, the waveform containing the at least one selected frequency.

These, and other, embodiments of the invention will be better appreciated and understood when considered in conjunction with the following description and the accompanying drawings. It should be understood, however, that the following description, while indicating various embodiments of the invention and numerous specific details thereof, is given by way of illustration and not of limitation. Many substitutions, modifications, additions and/or rearrangements may be made within the scope of the invention without departing from the spirit thereof, and the invention includes all such substitutions, modifications, additions and/or rearrangements.

### BRIEF DESCRIPTION OF THE DRAWINGS

The drawings accompanying and forming part of this specification are included to depict certain aspects of the invention. A clearer conception of the invention, and of the components and operation of systems provided with the invention, will become more readily apparent by referring to the exemplary, and therefore nonlimiting, embodiments illustrated in the drawings, wherein like reference numerals (if they occur in more than one view) designate the same or similar elements. The invention may be better understood by reference to one or more of these drawings in combination with the description presented herein. It should be noted that the features illustrated in the drawings are not necessarily drawn to scale.

FIG. 1 is a block diagram of a multiple frequency voltage generator, representing an embodiment of the invention.

FIG. 2 is a circuit diagram of a multi-frequency voltage generator incorporating a pair of cascaded H-bridges, representing an embodiment of the invention.

FIG. 3 is a cascaded H-bridge pair switching diagram, representing an embodiment of the invention.

FIG. 4 is a set of graphs of inverter voltages and switching device gate signals, illustrating an embodiment of the invention.

FIG. 5 is a graph of constraint curves of m₃ versus m₁ (positive-positive case) illustrating an embodiment of the invention.

FIG. 6 is a graph of step angle solutions for θ₁ and θ₂, for varying m₃ when m₁=1 (positive-positive case), illustrating an embodiment of the invention.

FIG. 7 is a graph of ratios of V₅, V₇, and V₉ to V₁, for varying m₃ when m₁=1 (positive-positive case), illustrating an embodiment of the invention.

FIG. 8 is a graph of constraint curves of m₃ versus m₁ (positive-negative case), illustrating an embodiment of the invention.

FIG. 9 is a graph of step angle solutions for θ₁ and θ₂, for varying m₃ when m₁=0.5 (PN case), illustrating an embodiment of the invention.

FIG. 10 is a graph of ratios of V₅, V₇, and V₉ to V₁ for varying m₃ when m₁=0.5 (PN case), illustrating an embodiment of the invention.

FIG. 11 is a graph of constraint curves of m₃ versus m₁ (positive-positive-positive case), illustrating an embodiment of the invention.

FIG. 12 is a graph of constraint curves of m₃ versus m₁ (positive-positive-negative case), illustrating an embodiment of the invention.

FIG. 13 is a graph of constraint curves of m₃ versus m₁ (positive-negative-positive case), illustrating an embodiment of the invention.

FIG. 14 is a graph of step angle solutions for maximum m₃ range when m₁=0.587785 (PNP case), illustrating an embodiment of the invention.

FIG. 15 is a graph of ratios of V₇, V₉, and V₁₁ to V₁, for varying m₃ when m₁=0.587785 (positive-negative-positive case), illustrating an embodiment of the invention.

FIG. 16 is a graph of constraint curves of m₃ versus m₁ (positive-negative-negative case), illustrating an embodiment of the invention.

FIG. 17 is a set of graphs of simulated multi-frequency waveform generation results, illustrating an embodiment of the invention.

FIG. 18 is a set of graphs of experimental multi-frequency waveform generation results, illustrating an embodiment of the invention.

FIG. 19 is a set of graphs of experimental multi-frequency waveform generation results from multi-level inverter with unequal DC sources, illustrating an embodiment of the invention.

FIG. 20 is a set of graphs of experimental multi-frequency waveform harmonic content results, illustrating an embodiment of the invention.

FIGS. 21a-21c are a set of graphs comparing actual step-angles to the approximating neural network outputs for various m₃ and m₁ values (for positive-negative case), illustrating an embodiment of the invention.

FIGS. 22a-22c are a set of graphs comparing actual step-angles to the approximating neural network outputs for various m₃ and m₁ values (for positive-negative-positive case), illustrating an embodiment of the invention.

### DETAILED DESCRIPTION

The invention and the various features and advantageous details thereof are explained more fully with reference to the nonlimiting embodiments that are illustrated in the accompanying drawings and detailed in the following description. It should be understood that the detailed description and the specific examples, while indicating specific embodiments of the invention, are given by way of illustration only and not by way of limitation. Various substitutions, modifications, additions and/or rearrangements within the spirit and/or scope of the underlying inventive concept will become apparent to those of ordinary skill in the art from this disclosure.

The invention includes methods and apparati for multiple frequency voltage generation. In one embodiment, the invention includes a method that enables a voltage converter to precisely produce an output voltage containing two or more select frequencies, each frequency at a desired level. In another embodiment, the invention includes a method that enables the production of a voltage containing two or more select frequencies, while simultaneously eliminating at least one undesirable frequency.

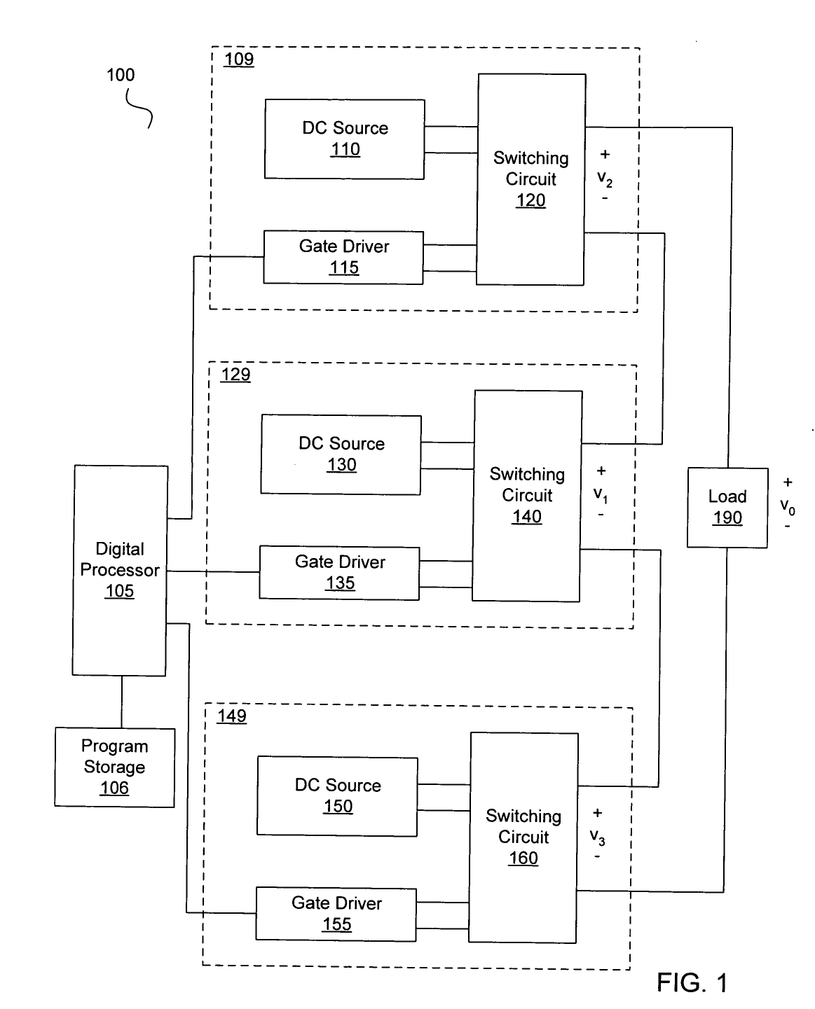

Referring to FIG. 1, a block diagram of a multiple frequency (multi-frequency) voltage generator 100 is depicted according to an aspect of the invention. A digital processor 105 is coupled to a program storage device 106 and to a set of gate drivers 115, 135, and 155. Each of the gate drivers 115, 135, and 155 is coupled to a set of switching circuits 120, 140, and 160, respectively. A set of DC sources 110, 130, and 150 is coupled to the switching circuits 120, 140, and 160. Switching circuit 120 is coupled to switching circuit 140, and switching circuit 140 is coupled to switching circuit 160. Switching circuits 120, 160 are coupled to an electrical load 190. The output voltage v₀ and cell component voltages v₁, v₂, and v₃ are indicated.

In this particular example, three converter circuits 109, 129, and 149 are shown. One of ordinary skill in the art will recognize that the number of converter circuits may vary in light of a particular application. Further, an AC source coupled to a plurality of AC-DC power converters may substitute DC sources 110, 130, and 150, and/or a gate driver array may substitute gate drivers 115, 135, and 155. In one embodiment, each of the DC sources 110, 130, and 150 may produce a different DC voltage. In another embodiment, a plurality of series capacitors with one DC source placed across them may substitute DC sources 110, 130, and 150. Those of ordinary skill in the art will recognize that there are other suitable source configurations that can be used.

In operation, the digital processor 105 may control gate drivers 115, 135, and 155 according to instructions stored in the program storage device 106. Each gate driver 115, 135, and 155 may apply a voltage to the gate of each switch of switching circuits 120, 140, and 160, producing a controlled multi-frequency voltage across the load 109.

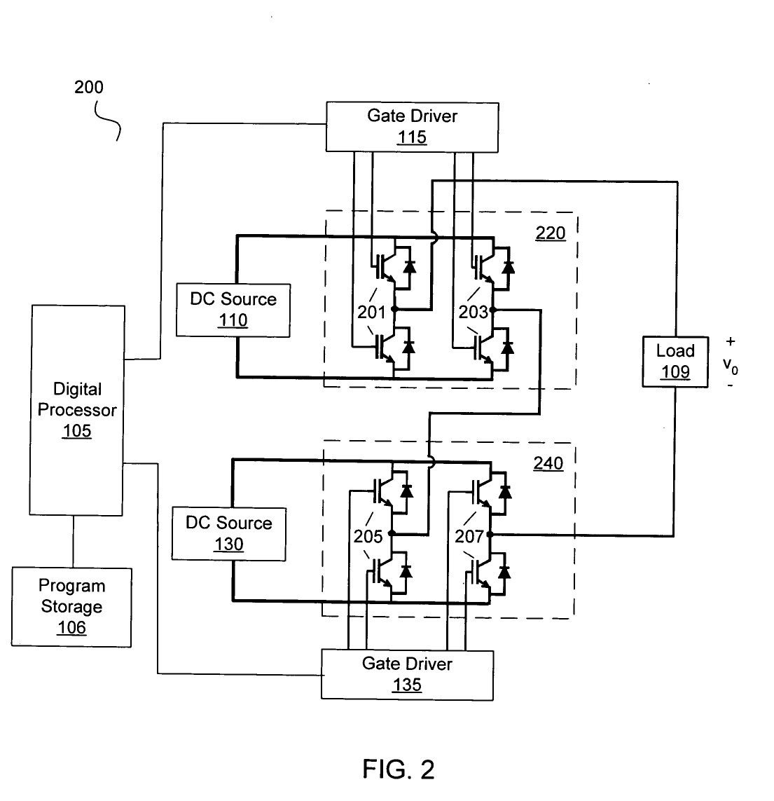

In practice, switching circuits 120, 140, and 160 may include solid state switching circuits, such as, for example, diode-clamped (neutral-point clamped), capacitor-clamped (flying capacitor), and cascaded H-bridge (shown in FIG. 2) switching circuits, all of which are well known in the art. Those of ordinary skill in the art will recognize that there are other suitable switching circuits that can be used. Further, the digital processor 105 may be implemented as an integrated circuit (IC). The digital processor 105 may be a programmable circuit, such as, for example, a microprocessor or digital signal processor-based circuit, that operates in accordance with instructions stored in the program storage media 106. The program storage media 106 may be any type of readable memory including, for example, a magnetic or optical media such as a card, tape or disk, or a semiconductor memory such as a PROM or FLASH memory. The digital processor 105 may be implemented in software, or the functions may be implemented by a hardware circuit, or by a combination of hardware and software.

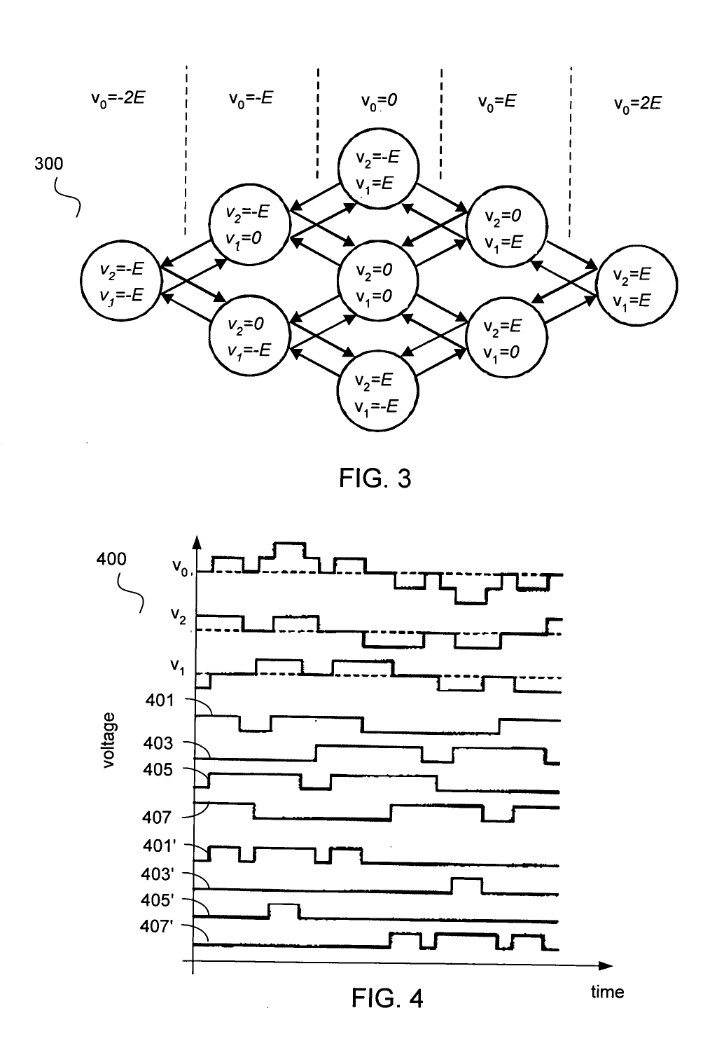

When the digital processor 105 is a programmable circuit, a program, such as that presented below and discussed in detail with reference to FIGS. 3-15, is stored in the program storage media 106 to create an apparatus in accordance with the present invention that operates in accordance with the methods of the present invention. In the alternative, the digital processor 105 may be hard-wired or may use predetermined data tables, or may be a combination of hard-wired and programmable circuitry.

Referring to FIG. 2, a circuit diagram of a multi-frequency voltage generator incorporating a pair of cascaded H-bridges 220 and 240 is depicted according to an aspect of the invention. Each H-bridge 220 and 240 may be used as a switching circuit, such as switching circuits 120, 140, and 160 detailed in FIG. 1. DC source 110 is coupled to a first H-bridge 220, which includes two pairs of transistors 201 and 203, and DC source 130 is coupled to a second H-bridge 240, which includes two pairs of transistors 205 and 207. Transistor pair 203 is coupled to transistor pair 205. Each transistor may be, for example, a field-effect transistor (FET), a power FET, or the like, and may include a clamping diode coupling its source to its drain. The output voltage v₀ and cell component voltages v₁ and v₂ are indicated.

In operation, the digital processor 105 may control the pair of gate drivers 115 and 135 according to instructions stored in the program storage device 106. Each gate driver 115 and 135 may apply a voltage to the gate of each transistor 201, 203, 205, and 207, producing a controlled multi-frequency voltage across the load 109.

Referring to FIG. 3, a cascaded H-bridge pair switching diagram 300 is depicted, illustrating an aspect of the invention. Each H-bridge cell such as the ones depicted in FIG. 2 may produce, for example, voltages of −E, 0, and E, where E is the voltage of the connected DC source, which may assume any value. The nine possible unique switching states of a pair of H-bridge cells cascaded together are outlined in diagram 300. State transition arrows indicate the path which minimizes commutation on the cell level. For example, if a transition is made from the state (v₂=−E, v₁=E) to (v₂=0, v₁=E), and it is desired to return to v₀=0, then the path indicated by the arrow should be followed to (v₂=0, v₁=0) in order to minimize cell commutation. Any zero cell states (states involving v₁=0 or v₂=0) may have further redundancy since the H-bridge structure can create a zero state in two different ways. In order to minimize commutation on the transistor level, this redundancy can be exploited by producing a similar state diagram for each cell.

Referring to FIG. 4, a set of graphs of the various inverter (DC to AC converter) voltages and transistor gate signals 400 is depicted according to an aspect of the invention. Graph 400 shows the output voltage v₀ and cell component voltages v₁ and v₂ as detailed in FIG. 2. Transistor gate signals 401, 403, 405, and 407 correspond to the top transistor of pairs 201, 203, 205, and 207, respectively, and are the result of the minimum commutation rules of FIG. 3. Moreover, the logical inverse of gate signals 401, 403, 405, and 407, correspond to the bottom transistor pair 201, 203, 205, and 207, respectively. It may be seen that the switching frequency of each transistor is the same and is twice that of the fundamental component. It can also be noted that the shortest pulse is approximately 8.3% of the fundamental period.

Transistor gate signals 401′, 403′, 405′, and 407′ also correspond to the top transistor of pairs 201, 203, 205, and 207, respectively, but now demonstrate switching pattern which may be generated by simply directly assigning the output voltage to switching states without regard to the commutation rules of FIG. 3. It can be seen that signals 401′ and 407′ switch at three times the fundamental frequency, and signals 403′ and 405′ switch at the fundamental frequency. Furthermore, the minimum pulse time is only approximately 4.2% of the fundamental. As one or ordinary skill in the art will recognize in light of this disclosure, these factors may constrain the achievable performance, power level and conversion efficiency.

Referring again to FIGS. 1 and 2, the invention may include a method for producing an output voltage v₀ containing two or more selected frequencies, each frequency at a desired level, while usually simultaneously eliminating at least one undesirable frequency. For an output voltage waveform that is quarter-wave symmetric with s positive steps of equal magnitude E (steps of unequal magnitude may also be used and can be treated accordingly) it is well-known that the waveform's Fourier series expansion is given by:

$${V}_{0} ( t ) = {\sum }_{odd h} \{ {V}_{h} sin ( h ωt ) \} \qquad Equation 1$$

where:

$${V}_{h} = \frac{4 E}{h π} [ cos ( h {θ}_{1} ) + cos ( h {θ}_{2} ) + … + cos ( h {θ}_{s} ) ] \qquad Equation 2$$

and the θᵢ,i=, . . . , s, are the angles (within the first quarter of each waveform cycle) at which the s steps occur. On the other hand, if a negative step, N, indicating down, instead of a positive step, P, indicating up, occurs at a particular θᵢ, the coefficient of the corresponding cosine term in Equation 2 is −1 instead of +1. For example, when synthesizing a stepped waveform that has desired levels of V₁ and V₃ with two of the adjacent higher harmonics equal to zero, the stepping angles 0≦θ_{1<θ}₂< . . . <θₛ≦π/2 may be chosen so that:

$$\begin{matrix}\frac{4 E}{π} [ cos ( {θ}_{1} ) + cos ( {θ}_{2} ) + … + cos ( {θ}_{s} ) ] = {V}_{1} & Equation 3 a \\ \frac{4 E}{3 π} [ cos ( 3 {θ}_{1} ) + cos ( 3 {θ}_{2} ) + … + cos ( 3 {θ}_{s} ) ] = {V}_{3} & Equation 3 b \\ cos ( 5 {θ}_{1} ) + cos ( 5 {θ}_{2} ) + … + cos ( 5 {θ}_{s} ) = 0 & Equation 3 c \\ cos ( 7 {θ}_{1} ) + cos ( 7 {θ}_{2} ) + … + cos ( 7 {θ}_{s} ) = 0 & Equation 3 d\end{matrix}$$

Again, if a step down instead of a step up occurs at a particular θᵢ, the coefficient of the corresponding cosine term in Equations 3a-d should be −1 instead of +1. Using the following identities:
cos(3θ)=4 cos(θ)³−3 cos(θ) Equation 4a
cos(5θ)=16 cos(θ)⁵−20 cos(θ)³+5 cos(θ) Equation 4b
cos(7θ)=64 cos(θ)⁷−112 cos(θ)⁵+56 cos(θ)³−7 cos(θ) Equation 4c
and defining cᵢ as cos(θᵢ), Equations 3a-d may be re-written as:

$$\begin{matrix}{\sum }_{i = 1 , … , s}^{} {c}_{i} = \frac{{V}_{1}}{( \frac{4 E}{π} )} = {m}_{1} & Equation 5 a \\ {\sum }_{i = 1 , … , s}^{} \{ 4 {c}_{i}^{3} - 3 {c}_{i} \} = \frac{{V}_{3}}{( \frac{4 E}{3 π} )} = {m}_{3} & Equation 5 b \\ {\sum }_{i = 1 , … , s}^{} \{ 16 {c}_{i}^{5} - 20 {c}_{i}^{3} + 5 {c}_{i} \} = 0 & Equation 5 c \\ {\sum }_{i = 1 , … , s}^{} \{ 64 {c}_{i}^{7} - 112 {c}_{i}^{5} + 56 {c}_{i}^{3} - 7 {c}_{i} \} = 0 & Equation 5 d\end{matrix}$$

Now the set of trigonometric Equations 3a-d has been transformed into a set of multivariate polynomial Equations 5a-d. The solution of Equations 5a-d may be found as follows. Given two polynomials:
f(x, y)=a₀(x)y^{l}+a₁(x)y^{l-1}+ . . . +a₁, a₀(x)≠0, l>0
g(x, y)=b₀(x)yⁿ+b₁(x)yⁿ⁻¹+ . . . +bₙ, b₀(x)≠0, n>0
all possible solutions (x*, y*) of f(x, y)=0 and g(x, y)=0 may be obtained by finding x* as the eigenvalues of the Sylvester matrix formed from the aⱼ(x), j=1, . . . , l, and bₖ(x), k=1, . . . , n, and then y* as the roots of f(x*, y)=0. Clearly, a necessary condition for the existence of nontrivial solutions to Equations 5a-d is that the number of steps s be greater than or equal to the number of constraint equations.

The invention may include, for example, a method for creating a 2-step (s=2) waveform with desired levels of 1^{st} and 3^{rd} harmonics, and a 3-step (s=3) waveform with desired levels of 1^{st} and 3^{rd} harmonics with simultaneous elimination of the 5^{th} harmonic. 2-step and 3-step waveform production methods are described below. As one of ordinary skill in the art will recognize, a multiple step waveform production method for simultaneously generating and possibly eliminating select frequencies may be readily derived from this disclosure by employing various well-known techniques for reducing s Equations in s variables to 2 Equations in 2 variables, where s is an integer greater than 2.

1. 2-Step Waveform

In the case of a 2-step waveform, two alternatives need to be considered: the PP case and the PN case, representing waveforms having two successive positive steps and a positive step followed by a negative step, respectively. Their negations, the NN case and NP case, simply result in solutions that are 180° phase-shifted respectively from the PP and PN solutions.

(i) The PP Case

The applicable Equations are, from Equations 5a-b:
c₁+c₂=m₁ Equation 6a
(4 c₁³−3 c₁)+(4 c₂³−3 c₂)=m₃ Equation 6b

Solving for c₁ and c₂ yields:

$$\begin{matrix}{c}_{1} = \frac{3 {m}_{1}^{2} + \sqrt{3} \sqrt{3 {m}_{1}^{2} - {m}_{1}^{4} + {m}_{1} {m}_{3}}}{6 {m}_{1}} & Equation 7 a \\ {c}_{2} = \frac{3 {m}_{1}^{2} - \sqrt{3} \sqrt{3 {m}_{1}^{2} - {m}_{1}^{4} + {m}_{1} {m}_{3}}}{6 {m}_{1}} & Equation 7 b\end{matrix}$$

From Equation 6a, it may be noted that for admissible c₁ and c₂, m₁ is restricted to a value between 0 and 2. Moreover, since c₁ and c₂ need to be real and greater than 0, these constrain m₁ and m₃ so that
m₁³−3m₁≦m₃≦4m₁³−3m₁, for 0≦m₁≦1 Equation8a
m₁³−3m₁≦m₃≦4m₁³−12m₁²+9m₁, for 1≦m₁≦2 Equation 8b

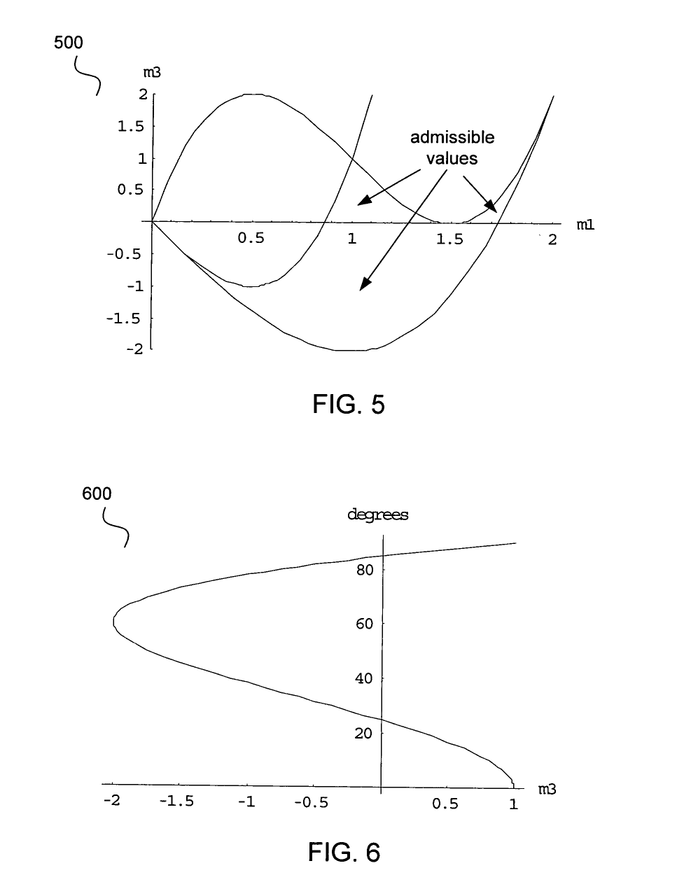

Referring to FIG. 5, a graph 500 of constraint curves of m₃ versus m₁ (PP case) is depicted, according to an aspect of the invention. The graph 500 of these constraint curves indicates that the range of possible m₃ is maximized at m₁=1.

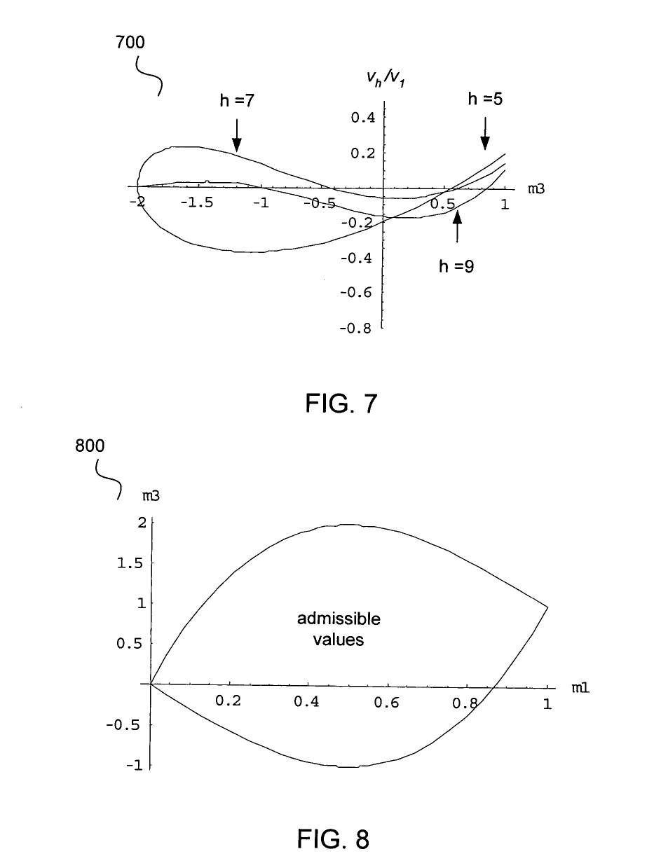

Referring to FIG. 6, a graph 600 of step angle solutions for θ₁ and θ₂, for varying m₃ when m₁=1 is depicted (PP case), according to an aspect of the invention. Referring to FIG. 7, a graph 700 of ratios of V₅, V₇, and V₉ (higher harmonic amplitudes) to V₁ for varying m₃ when m₁=1 (PP case) is depicted, according to an aspect of the invention. It may be noted that V₃/V₁=m₃/(3m₁). It may also be noted that this case requires the production of a 5-level waveform and (at least) a 2-cell converter such as the one depicted in FIG. 2. With a 2-cell converter, it is possible to turn on and turn off each switch at the fundamental frequency to produce the desired waveform.

(ii) The PN Case

The applicable Equations in this case are:
c₁−c₂=m₁ Equation 9a
(4 c₁³−3 c₁)−(4 c₂³−3 c₂)=m₃ Equation 9b
where the second halves of Equations 9a and 9b are the negative of those same parts of Equations 6a and 6b because the second step is down instead of up. Then substituting Equation 9a into Equation 9b, and solving for c₁ and c₂ yields:

$$\begin{matrix}{c}_{1} = \frac{3 {m}_{1}^{2} + \sqrt{3} \sqrt{3 {m}_{1}^{2} - {m}_{1}^{4} + {m}_{1} {m}_{3}}}{6 {m}_{1}} & Equation 10 a \\ {c}_{2} = \frac{- 3 {m}_{1}^{2} + \sqrt{3} \sqrt{3 {m}_{1}^{2} - {m}_{1}^{4} + {m}_{1} {m}_{3}}}{6 {m}_{1}} & Equation 10 b\end{matrix}$$

From Equation 9a, it may be noted that for admissible c₁ and c₂, m₁ is restricted to a value between 0 and 1. Moreover, since c₁ needs to be real and less than 1, this constrains m₁ and m₃ such that:
m₁³−3m₁≦m₃≦4m₁³−12m₁²+9m₁ Equation 11a
whereas since c₂ needs to be real and greater than 0, this constrains m₁ and m₃ such that:
m₁³−3m₁≦4m₁³−3m₁≦m₃ Equation 11b

Referring to FIG. 8, a graph 800 of constraint curves of m₃ versus m₁ (PN case) is depicted according to an aspect of the invention. The graph 800 indicates that the range of possible m₃ yielding admissible solutions is maximized at m₁=0.5.

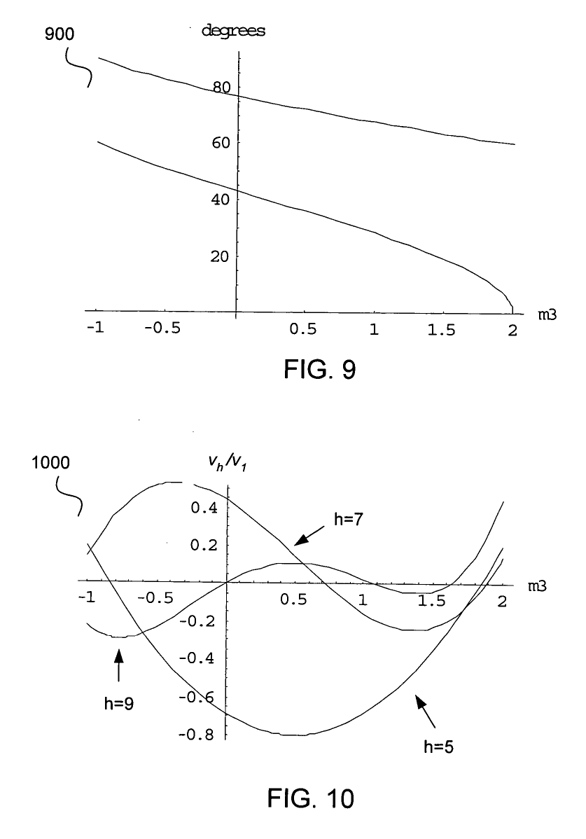

Referring to FIG. 9, a graph 900 of step angle solutions for θ₁ and θ₂, for varying m₃ when m₁=0.5 (PN case) is depicted according to an aspect of the invention. Referring to FIG. 10, a graph 1000 of ratios of V₅, V₇, and V₉ (higher harmonic amplitudes) to V₁ for varying m₃ when m₁=0.5 (PN case) is depicted according to an aspect of the invention. It may be noted that this case requires the production of a 3-level waveform and (at least) a 1-cell converter. With a 1-cell converter, the switches can be operated so that each turns on and turns off at twice the fundamental frequency. With a 2-cell converter, it is possible to turn on and turn off each switch at the fundamental frequency to produce the desired waveform.

In conclusion, for the 2-step case to generate desired levels of 1^{st} and 3^{rd} harmonics, the PP waveform results in lower harmonic distortion compared to the PN waveform but requires a 5-level waveform instead of a 3-level waveform. Moreover, for required magnitudes of m₃≦1 with the PP waveform, positive m₃ is preferable to negative m₃ for reduced distortion. However, the PN waveform allows a broader range of achievable 1^{st} and 3^{rd} harmonic level combinations.

2. 3-Step Waveform

In the case of a 3-step waveform, four possible combinations need to be considered, excluding those that are the negations (for the same reasons explained with respect to the 2-step waveform) of the following cases: PPP, PPN, PNP and PNN.

The applicable Equations are, from Equations 5a-c:
c₁+k₂c₂+k₃c₃=m₁ Equation 12a
(4c₁³−3c₁)+k₂(4c₂³−3c₂)+k₃(4c₃³−3c₃)=m₃ Equation 12b
(16c₁⁵−20c₁³+5c₁)+k₂(16c₂⁵+20c₂³+5c₂)+k₃(16c₃⁵−20c₃³+5c₃)=0 Equation 12c
where k₂, k₃ are separately either +1 or −1 for a positive step or a negative step, respectively. Substituting the expression for c₃ from Equations 12a into 12b and 12c yields two nonlinear polynomial Equations in terms of c₁ and c₂. The exact solution of such Equations (as opposed to running a search algorithm) is, in general, computationally intensive and increasingly difficult as the number of variables increases. For two Equations with two variables, however, the procedure for calculating the 3-step angle solutions is relatively straight forward and may be summarized as follows:

First, from Equation 12a, c₃(c₁, c₂) is substituted into 12b and 12c to obtain two polynomial Equations in c₁ and c₂. Next, from the two polynomials f(c₁, c₂) and g(c₁, c₂), the coefficients of the powers of c₂ are extracted and labeled appropriately as a₀, a₁, . . . , a₁, b₀, b₁, . . . , bₙ. Then the Sylvester matrix is formed with these coefficients and its eigen values are found. The eigenvalues are candidate solutions for c₁, which also needs to be a real number and satisfy 0≦c₁≦1; inadmissible ones may be discarded.

Next, for each remaining candidate solution for c₁, its value may be substituted into f(c₁, c₂) and candidate solutions for c₂ may be found, which needs to be a real number and satisfy 0≦c₂≦c₁; inadmissible ones may be discarded. For each remaining candidate solution for c₂, its value and the corresponding candidate solution for c₁ may be substituted into Equation 12a to find the candidate solution for c₃ in our problem, which needs to be a real number and satisfy 0≦c₃≦c₂ (in order for it to be admissible). Finally, the admissible triples of (c₁, c₂, c₃) are the solution(s) to the 3-step waveform problem.

In each case, the limits of m₁ and m₃ for the existence of admissible solutions may be determined from Equations 12a-c. These limits are defined by the requirement for c₁, c₂, c₃ to be real and, by definition of their relationship, for c₁ to be less than 1 and c₃ to be greater than 0. Then, the value of m₁ yielding the maximum range of m₃ may be determined and the step-angles for this particular m₁ value found by solving Equation 12 iteratively for incrementally increasing values of m₃. These solutions may then allow the corresponding higher harmonic amplitudes to be plotted to gauge the amount of waveform distortion for optimization purposes.

(i) The PPP Case

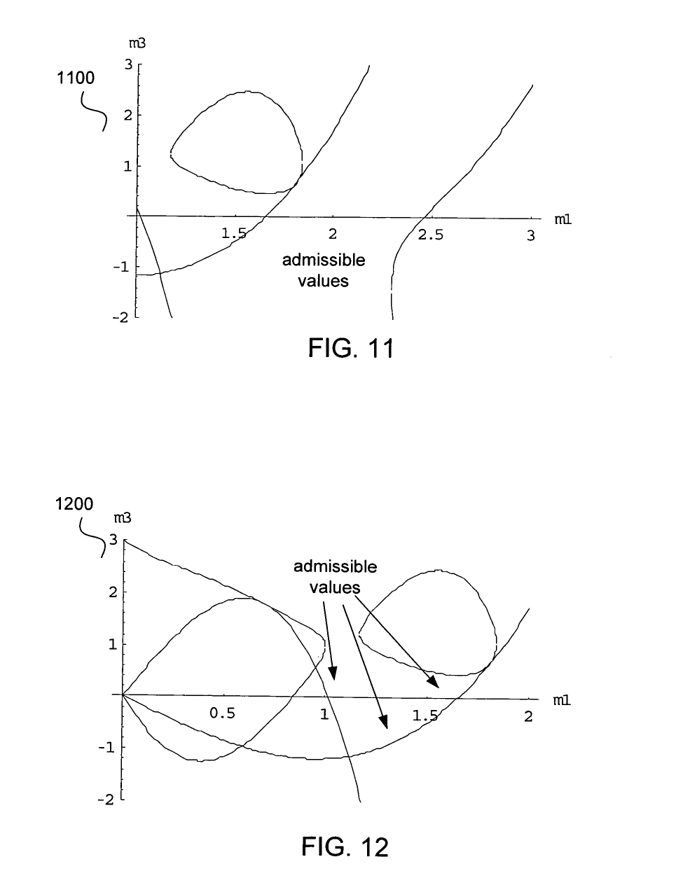

In this case, solutions exist and may be unique for the range of m₁ and m₃ delineated by the constraint curves 1100 of FIG. 11. The value of m₁ yielding the maximum range of m₃ is approximately 1.8. This case requires the production of a 7-level waveform and (at least) a 3-cell converter. With a 3-cell converter, it is possible to turn on and turn off each switch at the fundamental frequency to produce the desired waveform.

(ii) The PPN Case

In this case, solutions exist and may be unique for the range of m₁ and m₃ delineated by the constraint curves 1200 of FIG. 12. The value of m₁ yielding the maximum range of m₃ is about 1.1. This case requires the production of a 5-level waveform and (at least) a 2-cell converter. With a 3-cell converter, it is possible to turn on and turn off each switch at the fundamental frequency to produce the desired waveform.

(iii) The PNP Case

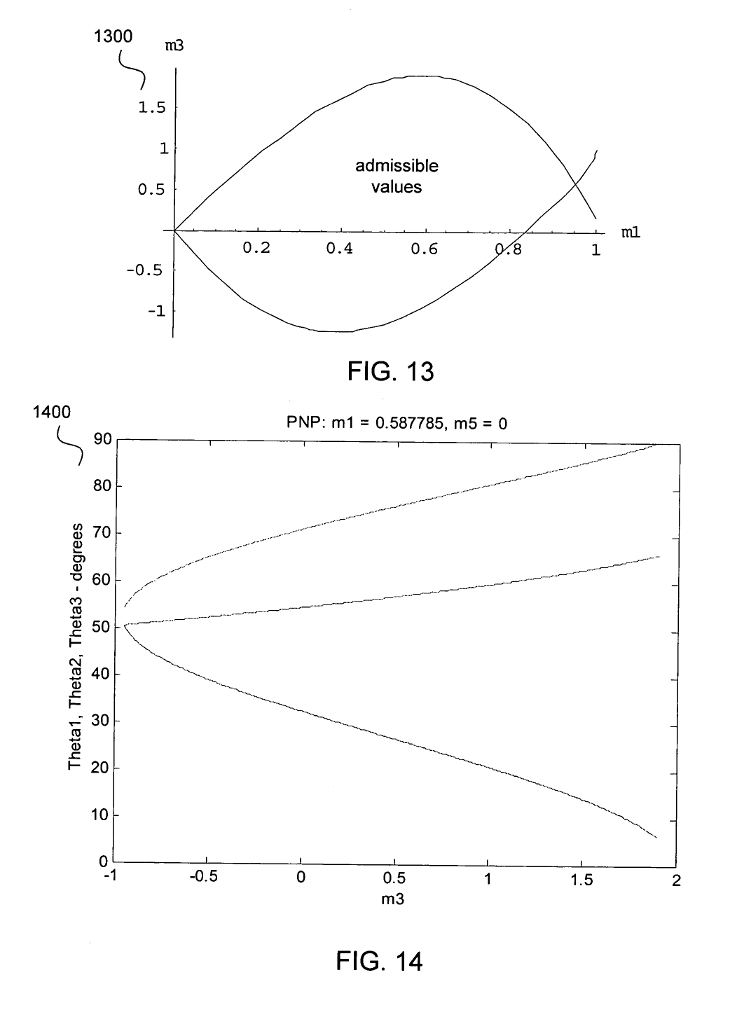

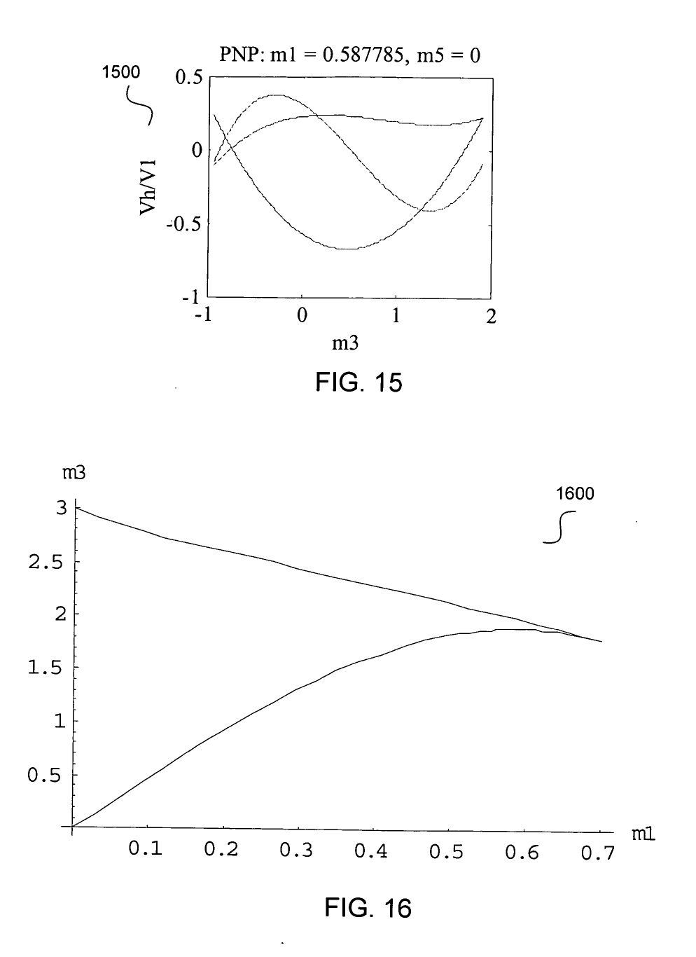

In this case, solutions exist and may be unique for the range of m₁ and m₃ delineated by the constraint curves 1300 of FIG. 13. The value of m₁ yielding the maximum range of m₃ is approximately 0.588. FIG. 14 is a graph of step angle solutions for the maximum m₃ range for the PNP case, and FIG. 15 is a graph of ratios of V₇, V₉, and V₁₁ (higher harmonic amplitudes) to V₁. This case requires the production of just a 3-level waveform and (at least) a 1-cell converter. With a 3-cell converter, it is possible to turn on and turn off each switch at the fundamental frequency to produce the desired waveform.

(iv) The PNN Case

In this case, solutions exist and may be unique for the range of m₁ and m₃ delineated by the constraint curves 1600 of FIG. 16. The value of m₁ yielding the maximum range of m₃ is at 0. This case requires the production of just a 3-level waveform and (at least) a 1-cell converter. With a 3-cell converter, it is possible to turn on and turn off each switch at the fundamental frequency to produce the desired waveform.

In conclusion, for the 3-step case, the PNP waveform allows for a broad range of achievable 1^{st} and 3^{rd} harmonic level combinations. Moreover, it only requires producing a 3-level waveform. However, to have all devices operate at the fundamental frequency to produce this waveform requires a 3-cell converter.

### EXAMPLES

Specific embodiments of the invention will now be further described by the following, nonlimiting examples which will serve to illustrate in some detail various features. The following examples are included to facilitate an understanding of ways in which the invention may be practiced. It should be appreciated that the examples which follow represent embodiments discovered to function well in the practice of the invention, and thus can be considered to constitute preferred modes for the practice of the invention. However, it should be appreciated that many changes can be made in the exemplary embodiments which are disclosed while still obtaining like or similar result without departing from the spirit and scope of the invention. For example, one can perform embodiments including the summation of two or more quarter-wave symmetric waveforms designed according to the methodologies described above. Accordingly, the examples should not be construed as limiting the scope of the invention.

### Example 1

### Simulated Waveform

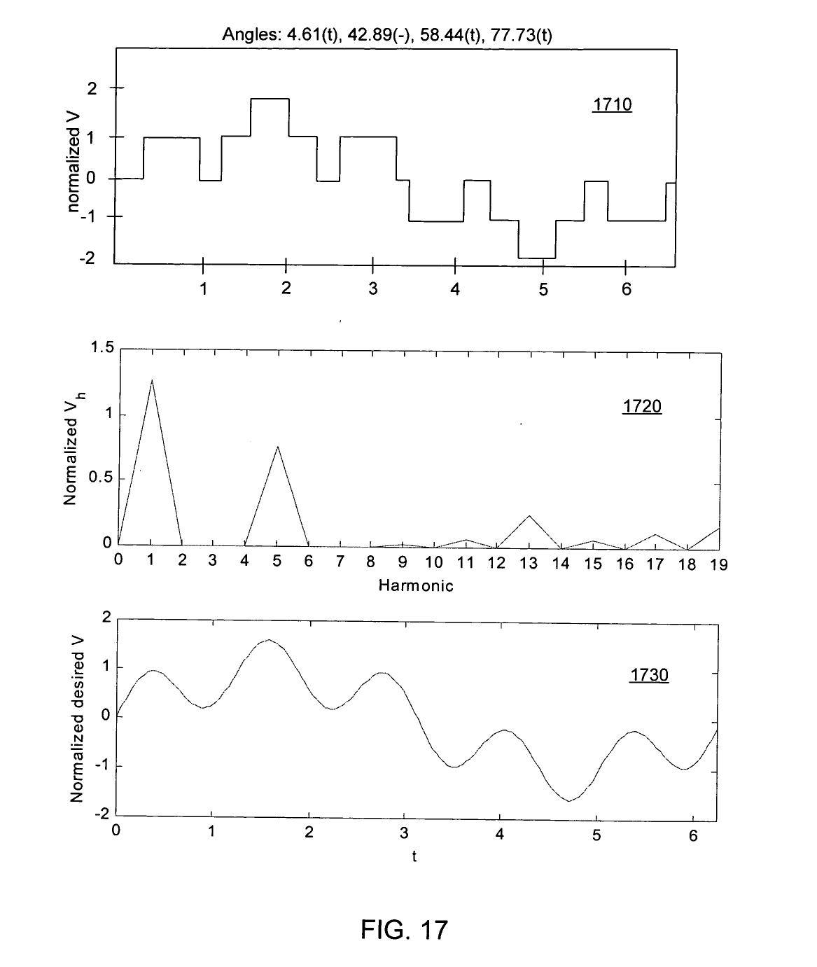

As a specific example of dual-frequency harmonic generation, consider the case where a span of 5 is required between the fundamental frequency component and the desired harmonic, e.g., 10 kHz and 50 kHz, respectively. FIG. 17 shows a set of graphs of simulated waveform generation. A five level step voltage waveform (normalized) 1710 was determined with step angles being designed to also eliminate the 3^{rd} and 7^{th} harmonics. As can be seen from the normalized harmonic spectrum 1720, the 9^{th} and 11^{th} harmonics are small as well, which means that the desired dual-frequency voltage waveform 1730 may be closely approximated with a small amount of filtering where necessary. In an induction heating application, for example, the induction coil's impedance naturally attenuates the various frequency components in proportion to their frequencies in converting the voltage to current, which dual-frequency approximation is of greater importance than the voltage. In other applications, an inductive filter may be added.

### Example 2

### Experimental Waveform Using Equal DC Source Values

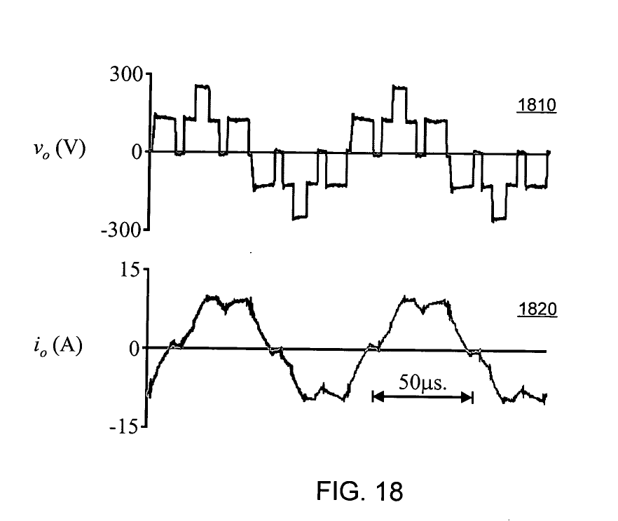

Laboratory measurements were obtained from a 5-level inverter demonstrating a 4-step PNPP case to generate 1^{st} and 5^{th} harmonics with V₅/V₁=0.6 while canceling the 3^{rd} and 7^{th} harmonics. Such a waveform may be desired, for example, in an induction heating application where a span of 5 is needed between the two heating frequencies. FIG. 18 shows a set of graphs of experimental waveform generation results. Graph 1810 shows the voltage waveform and graph 1820 shows the current waveform (for an inductive impedance load) for a fundamental frequency of 10 kHz and a (phase-shifted) harmonic of 50 kHz.

In this example, each DC voltage level (for a 2-cell cascaded H-bridge converter) was 125 V, the (R-L) load average power was approximately 513 W and the conversion efficiency was approximately 91.3% (with each switch operating at 20 kHz). The step angles were set at θ₁=4.61°, θ₂=42.89°, θ₃32 58.44°, and θ₄=77.73°. Table 1 shows a comparison of analytical and measured harmonic amplitudes indicating good agreement between them. It may be noted that the higher harmonics are mostly filtered out by the load inductance resulting mainly in the desired dual-frequency current.

TABLE 1

| | V₁ | V₃ | V₅ | V₆ | V₇ | V₁₁ | V₁₃ | V₁₅ |
|---|---|---|---|---|---|---|---|---|
| Analytical | 159.1 | 0 | 95.5 | 0 | 3.2 | 7.5 | 31.4 | 7.6 |
| Measured | 156.8 | 2.7 | 98.1 | 2.2 | 3.0 | 10.1 | 33.9 | 7.6 |

In the case of induction heating applications, only sporadic, off-line frequency and power level adjustments may be needed. In one embodiment, the step angles of a multilevel converter can be programmed as lookup tables depending on output voltage frequency span and component amplitude ratios.

### Example 3

### Experimental Waveform Using Unequal DC Source Values

As noted above, the DC source values may not be identical. As such, a quarter-wave symmetric waveform with s steps of magnitudes Eᵢ, i=1, . . . , s, has a Fourier series expansion that is given by Equation 1 but with

$${V}_{h} = \frac{4}{h π} [ {E}_{1} cos ( h {θ}_{1} ) \pm {E}_{2} cos ( h {θ}_{2} ) \pm … \pm {E}_{s} cos ( h {θ}_{s} ) ] \qquad Equation 13$$

where θᵢ, i=1, . . . , s, are the angles (within the first quarter of each waveform cycle) at which the s steps occur and the signs are either + or − depending on whether a positive step or a negative step occurs at a particular θᵢ.

For a specific problem of synthesizing a stepped waveform that has desired levels of V₁ and V₃ with two of the adjacent higher harmonics equal to zero, the step angles 0≦θ₁≦θ₂≦ . . . ≦θₛ≦π/2 may be chosen so that

$$\begin{matrix}\frac{4}{π} [ {E}_{1} cos ( {θ}_{1} ) \pm {E}_{2} cos ( {θ}_{2} ) \pm … \pm {E}_{s} cos ( {θ}_{s} ) ] = {V}_{1} & Equation 14 a \\ \frac{4}{3 π} [ {E}_{1} cos ( 3 {θ}_{1} ) \pm {E}_{2} cos ( 3 {θ}_{2} ) \pm … \pm {E}_{s} cos ( 3 {θ}_{s} ) ] = {V}_{3} & Equation 14 b \\ [ {E}_{1} cos ( 5 {θ}_{1} ) \pm {E}_{2} cos ( 5 {θ}_{2} ) \pm … \pm {E}_{s} cos ( 5 {θ}_{s} ) ] = 0 & Equation 14 c \\ [ {E}_{1} cos ( 7 {θ}_{1} ) \pm {E}_{2} cos ( 7 {θ}_{2} ) \pm … \pm {E}_{s} cos ( 7 {θ}_{s} ) ] = 0 & Equation 14 d\end{matrix}$$

again with the signs being either + or − depending on the corresponding step direction. Next, applying the identities in Equation 4a-c and defining ρᵢ=Eᵢ/Eₛ allow Equations 14a-d to be rewritten as

$$\begin{matrix}{\sum }_{i = 1 , … , s}^{} {ρ}_{i} {c}_{i} = \frac{{V}_{1}}{4 {E}_{s} / π} = {m}_{1} & Equation 15 a \\ {\sum }_{i = 1 , … , s}^{} {ρ}_{i} \{ 4 {c}_{i}^{3} - 3 {c}_{i} \} = \frac{{V}_{3}}{4 {E}_{s} / 3 π} = m3 & Equation 15 b \\ {\sum }_{i = 1 , … , s}^{} {ρ}_{i} \{ 16 {c}_{i}^{5} - 20 {c}_{i}^{3} + 5 {c}_{i} \} = 0 & Equation 15 c \\ {\sum }_{i = 1 , … , s}^{} {ρ}_{i} \{ 64 {c}_{i}^{7} - 112 {c}_{i}^{5} + 56 {c}_{i}^{3} - 7 {c}_{i} \} = 0 & Equation 15 d\end{matrix}$$

This set of multivariate polynomial equations may then be solved using the same procedures as for the case of equal DC source values.

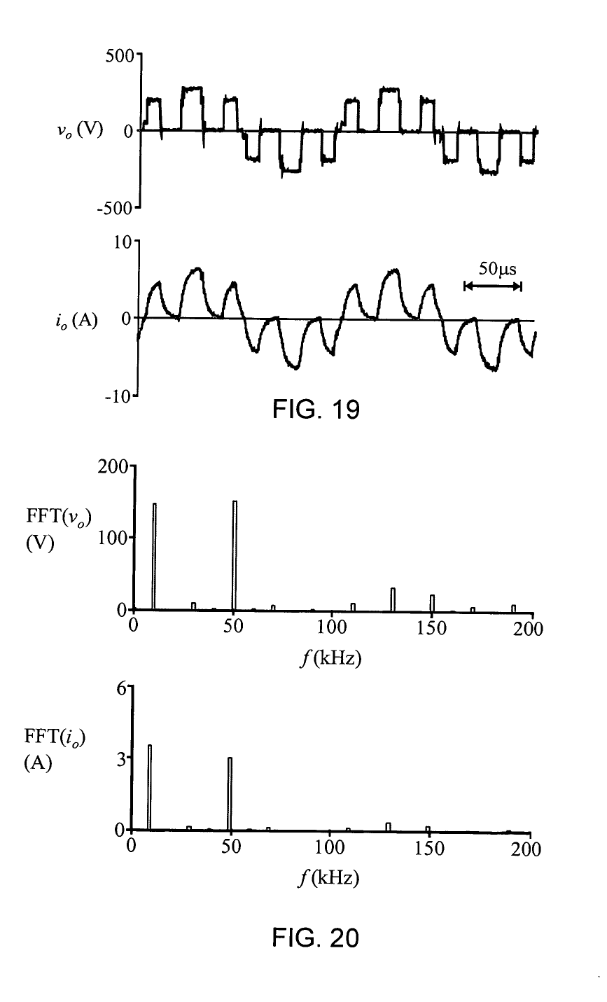

For example, laboratory measurements were obtained from a 5-level inverter demonstrating the unequal DC source (with E₁=E₂=E₃=200V, E₄=67V) 4-step PNPP case to generate desired 1^{st} and 5^{th} harmonic levels with V₅/V₁=1.0 while canceling the 3^{rd} and 7^{th} harmonics. This waveform may be desired for an application where a span of 5 is needed between two heating frequencies. The step angles were set to θ₁=9.09°, θ₂=34.43°, θ₃=69.73°, θ₄=74.17° (as appropriately calculated). FIG. 19 shows the voltage and current waveforms for a fundamental frequency of 10 kHz. The R-L load average power was 437.5 W and conversion efficiency was estimated to be 95.6% (from estimate of the IGBT dual-module losses based on datasheet values). Table 2 shows a comparison of the analytical and measured voltage harmonic amplitudes indicating good agreement between them. Note that the higher harmonics are mostly filtered out by the load inductance resulting mainly in the desired dual-frequency current as shown in FIG. 20.

TABLE 2

| | V₁ | V₃ | V₅ | V₆ | V₇ | V₁₁ | V₁₃ | V₁₅ |
|---|---|---|---|---|---|---|---|---|
| Analytical | 153.0 | 0 | 153.0 | 0 | 10.0 | 12.0 | 32.5 | 22.9 |
| Measured | 145.3 | 8.4 | 150 | 6.1 | 1.7 | 9.7 | 33.2 | 22.8 |

### Example 4

### A Neural Network Implementation of Dual-Frequency Output Control for Multilevel Inverters

A multilayer feedforward neural network can be used to implement the modulation indices to step-angle mappings for the control of a multilevel inverter-based dual-frequency induction heating power supply discussed above. The multilayer feedforward neural network was first trained, using either one processor or more processors to reduce the training time, to approximate the modulation indices to step-angle mappings for the PN case. This neural network consisted of two inputs (m₁ and m₃), two outputs (the values of cos(θ₁) and cos(θ₂)), and a single hidden layer of neurons. The binary sigmoid activation function was used for each neuron. For the purpose of training, the input values of m₁ were between 0 and 1 (in increments of 0.05) and the values of m₃ were also in increments of 0.05, while the desired output values were the cosines of the corresponding θ₁ and θ₂. A backpropagation algorithm was used to train the neural network: the value of the learning rate (α) was set to 0.8 and the momentum term was set to 0.9. In order to achieve an error of less than 2% after 3000 epochs of training, at least 16 hidden layer neurons were used.

For the PNP case, the neural network consisted of two inputs (m₁ and m₃) and a single hidden layer of neurons, but three outputs instead of two, i.e., cos(θ₁), cos(θ₂) and COS(θ₃). Again, a backpropagation algorithm was used to train the neural network for input values of m₁ and m₃ in increments of 0.05 and corresponding outputs of cos(θ₁), cos(θ₂) and COS(θ₃), with a learning rate of 0.3 and a momentum value of 0.9. In order to achieve an error of less than 4% after 3000 epochs of training, at least 32 hidden layer neurons were used.

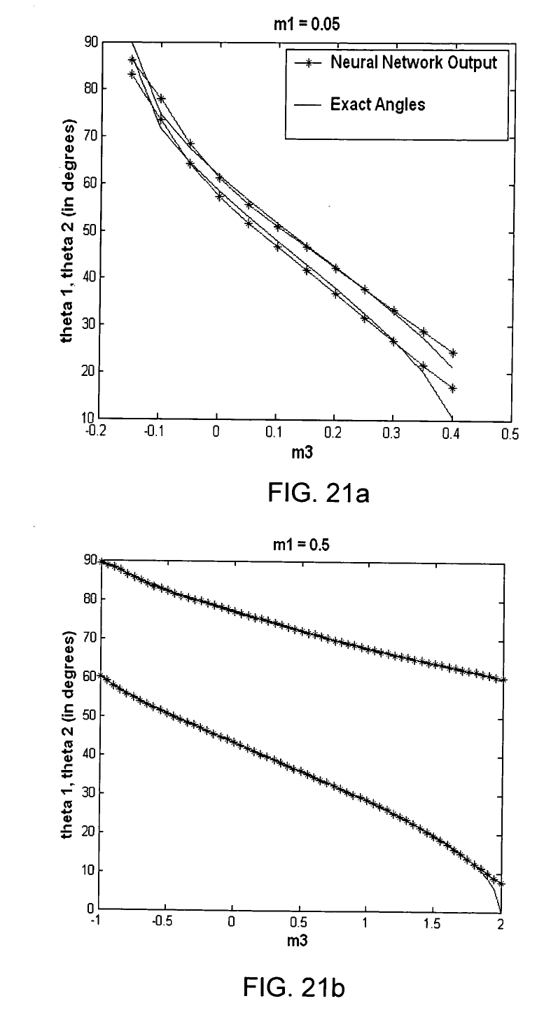

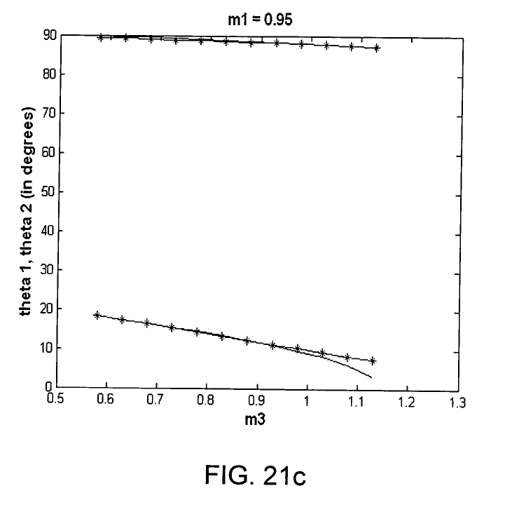

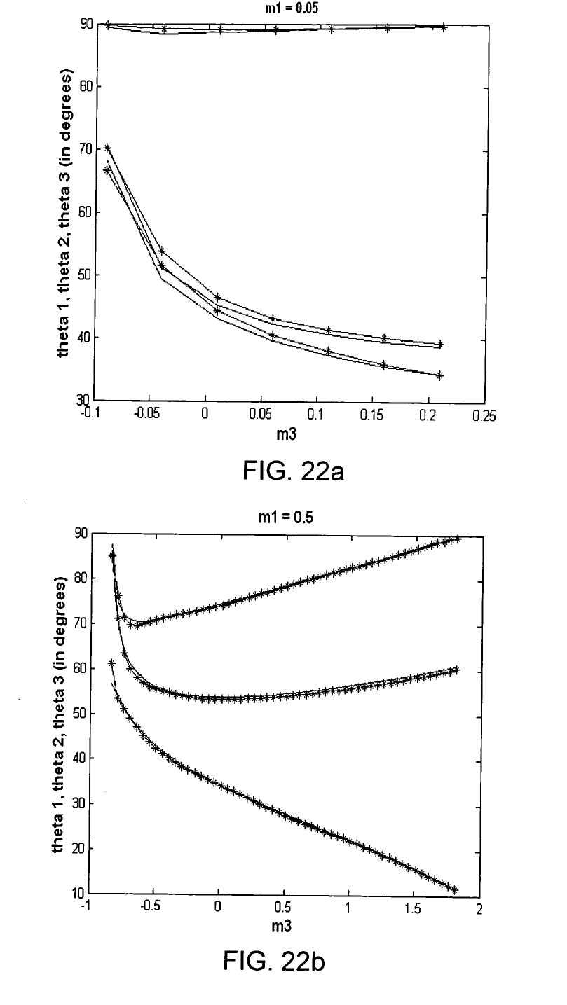

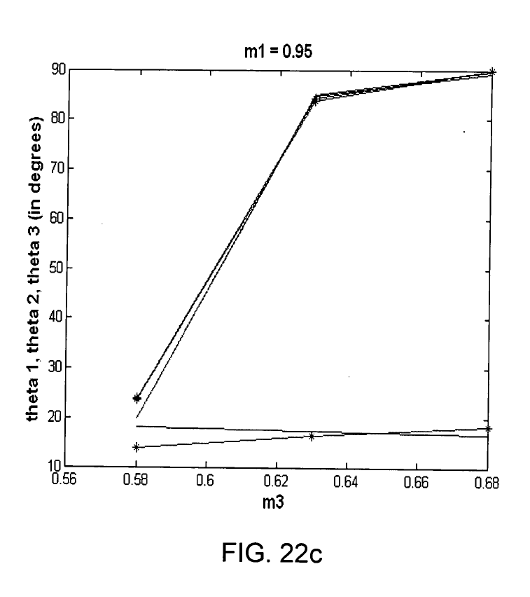

The trained neural networks were verified for different values of the input indices. It was found that the output values computed by the networks closely coincided with the actual calculated angles. However, there were slight discrepancies near the limits of the admissible range of values for m₁ and m₃. The graphs of step-angles (comparing the actual values to the approximating neural network outputs) versus m₃ value for low, medium and high values of m₁ are shown in FIG. 21a-c and FIG. 22a-c for the PN and PNP cases, respectively.

With the benefit of the present disclosure, those having skill in the art will comprehend that techniques claimed herein may be modified and applied to a number of additional, different applications, achieving the same or a similar result. The claims attached hereto cover all such modifications that fall within the scope and spirit of this disclosure.

The terms a or an, as used herein, are defined as one or more than one. The term plurality, as used herein, is defined as two or more than two. The term another, as used herein, is defined as at least a second or more. The terms including and/or having, as used herein, are defined as comprising (i.e., open language). The term coupled, as used herein, is defined as connected, although not necessarily directly, and not necessarily mechanically. The term approximately, as used herein, is defined as at least close to a given value (e.g., preferably within 10% of, more preferably within 1% of, and most preferably within 0.1% of). The term program, computer program, or software, as used herein, is defined as a sequence of instructions designed for execution on a computer system. A program may include, for example, a subroutine, a function, a procedure, an object method, an object implementation, an executable application, and/or other sequence of instructions designed for execution on a computer system.

1. A method for producing a multi-frequency voltage waveform, comprising:
identifying at least one selected frequency;
determining a number of steps and the direction of each step;
calculating a plurality of stepping angles as a function of the at least one selected frequency, the number of steps, and the direction of each step; and
producing a multi-frequency voltage waveform as a function of the stepping angles, the waveform containing the at least one selected frequency.

2. The method of claim 1, further comprising identifying at least one undesired frequency.

3. The method of claim 2, where calculating the plurality of stepping angles includes calculating the plurality of stepping angles as a function of the at least one undesired frequency.

4. The method of claim 2, where producing the multi frequency voltage waveform includes producing a multi-frequency voltage waveform not containing the at least one undesired frequency.

5. A computer readable medium comprising instructions to execute the method of claim 1.

6. A method for producing a multi-frequency voltage waveform, comprising:
steps for identifying at least one selected frequency;
steps for determining a number of steps and the direction of each step;
steps for calculating a plurality of stepping angles as a function of the at least one selected frequency, the number of steps, and the direction of each step; and
producing a multi-frequency voltage waveform as a function of the stepping angles, the waveform containing the at least one selected frequency.

7. The method of claim 6, further comprising steps for identifying at least one undesired frequency.

8. The method of claim 7, where steps for calculating the plurality of stepping angles comprise steps for calculating the plurality of stepping angles as a function of the at least one undesired frequency.

9. The method of claim 7, where steps for producing the multi frequency voltage waveform comprise steps for producing a multi-frequency voltage waveform not containing the at least one undesired frequency.

10. An apparatus for producing a multifrequency voltage waveform, comprising:
a processor, the processor calculating a plurality of stepping angles as a function of at least one selected frequency, a number of steps, and the direction of each step;
a plurality of gate drivers coupled to the processor;
a plurality of switching circuits coupled to the plurality of gate drivers, each of the plurality of switching circuits coupled to the next in a cascade configuration for producing a multi-frequency voltage waveform as a function of the plurality of stepping angles, the waveform containing the at least one selected frequency; and
a plurality of DC sources coupled to the plurality of switching circuits.

11. The apparatus of claim 10, the plurality of DC sources including an AC source coupled to a plurality of power converters.

12. The apparatus of claim 10, where each of the plurality of DC sources provides a substantially equal DC voltage.

13. The apparatus of claim 10, where each of the plurality of DC sources provides different DC voltages.

14. The apparatus of claim 10, the plurality of switching circuits comprising a plurality of diode-clamped circuits.

15. The apparatus of claim 10, the plurality of switching circuits comprising a plurality of capacitor-clamped circuits.

16. The apparatus of claim 10, further comprising a program storage device coupled to the digital processor for storing instructions to the processor.

17. The apparatus of claim 10, the processor comprising a neural network.

18. A system comprising:
a neural network;
a processor for training the neural network for determining a number of steps and the direction of each step;
calculating a plurality of stepping angles as a function of the at least one selected frequency, the number of steps, and the direction of each step; and
producing a multi-frequency voltage waveform as a function of the stepping angles, the waveform containing the at least one selected frequency.

19. The system of claim 18, the neural network comprising a plurality of neuron layers.

20. The system of claim 18, where the system further comprising:
a plurality of gate drivers coupled to the neural network;
a plurality of switching circuits coupled to the plurality of gate drivers, each of the plurality of switching circuits coupled to the next in a cascade configuration for producing a multi-frequency voltage waveform as a function of the plurality of stepping angles, the waveform containing the at least one selected frequency; and
a plurality of DC sources coupled to the plurality of switching circuits.
